(19) United States
(12) Patent Application Publication
(10) Pub. No.: US 2016/0379799 A1
(43) Pub. Date: Dec. 29, 2016

(54) TRIPLE MODE ELECTROSTATIC COLLIMATOR

(71) Applicant: Varian Semiconductor Equipment Associates, Inc., Gloucester, MA (US)

(72) Inventors: Frank Sinclair, Boston, MA (US); Victor M. Benveniste, Lyle, WA (US)

(21) Appl. No.: 15/262,087

(22) Filed: Sep. 12, 2016

Related U.S. Application Data
(62) Division of application No. 14/091,528, filed on Nov. 27, 2013.

(51) Int. Cl. H01J 37/317

(52) U.S. Cl. CPC H01J 37/3171; H01J 2237/047; H01J 2237/2485

(57) ABSTRACT

A system includes a first electrode to receive an ion beam, a second electrode to receive the ion beam after passing through the first electrode, the first and second electrode forming an upstream gap defined by a convex surface on one of the first or second electrode and concave surface on the other electrode, a third electrode to receive the ion beam after passing through the second electrode, wherein the second and third electrode form a downstream gap defined by a convex surface on one of the second or third electrode and concave surface on the other electrode, wherein the second electrode has either two concave surfaces or two convex surfaces; and a voltage supply system to independently supply voltage signals to the first, second and third electrode, that accelerate and decelerate the ion beam as it passes through the first, second, and third electrode.

### CROSS REFERENCE TO RELATED APPLICATIONS

This application is a continuation of U.S. patent application Ser. No. 14/091,528 filed Nov. 27, 2013, which is herein incorporated by reference in its entirety.

### FIELD

The present embodiments relate to an ion implantation apparatus, more particularly, to collimation control of an ion beam in ion implanter.

### BACKGROUND

Present day ion implanters are often used to irradiate flat substrates over a large dimension. To facilitate large area irradiation ion beam collimation may be performed to collimate a divergent ion beam before the ion beam impacts the substrate. Collimators are used in both ribbon beam ion implanters that direct a wide ribbon beam to a substrate that is invariant in time, as well as in spot beam ion implanters in which a spot beam or pencil beam is scanned back and forth to generate a ribbon cross-section.

It is also often convenient to propagate an ion beam through most of a beamline at its original energy as extracted from an ion source, or energy higher than extracted from the ion source, to improve ion beam transmission efficiency. This may especially be the case for ion energies lower than 100 keV, which energy range is increasingly used to perform ion implantation into advance microelectronic devices that employ shallower implantation depths. Accordingly, both collimation and any deceleration or acceleration of an ion beam may be performed downstream toward a substrate end of a beamline of the ion implanter.

In an electrostatic collimator, an electrostatic lens contains curved electrodes whose shape is arranged to collimate a diverging ion beam. In principle an electrostatic lens could be configured as a collimator and as an acceleration and deceleration lens. In particular, for known electrostatic lens systems collimation is more properly achievable under conditions in which the acceleration or deceleration applied to the ion beam is relatively large. However, constructing such an electrostatic lens becomes difficult when only modest changes in energy are desirable This is because such electrostatic lens systems would require excessive curvature in the lens electrodes to operate properly to collimate an ion beam, which may render such implementation impractical. It is with respect to these and other considerations that the present improvements have been needed.

### SUMMARY

In one embodiment, an electrostatic lens system includes a first electrode having a first opening to receive an ion beam; a second electrode having a second opening to receive the ion beam after passing through the first opening of the first electrode, wherein the first and second electrode form an upstream gap therebetween that is defined by a convex surface on one of the first or second electrodes and a concave surface on the other of the first or second electrodes; a third electrode having a third opening to receive the ion beam after passing through the second opening of the second electrode, wherein the second and third electrode form a downstream gap therebetween that is defined by a convex surface on one of the second or third electrodes and a concave surface on the other of the second or third electrodes, and wherein the second electrode has either two concave surfaces or two convex surfaces; and a voltage supply system to independently supply voltage to each of the first electrode, the second electrode, and the third electrode, and configured to generate voltage signals to accelerate and decelerate the ion beam when the ion beam passes through the first, second, and third electrode.

In another embodiment, a method of treating a diverging ion beam, comprising accelerating and partially collimating the diverging ion beam between a first electrode and a second electrode to create an accelerated and partially collimated ion beam; and decelerating the accelerated and partially collimated ion beam between the second electrode and a third electrode to generate a fully collimated ion beam.

### BRIEF DESCRIPTION OF THE DRAWINGS

FIG. 1 presents a block diagram of an ion implanter consistent with various embodiments of the disclosure;

FIG. 2 presents a block diagram of an ion implanter consistent with various embodiments of the disclosure;

FIG. 3A depicts a top view of an electrostatic lens system according to various embodiments;

FIG. 3B depicts an isometric view of an electrostatic lens of the system of FIG. 3A;

FIG. 4A depicts one scenario for use of the system of FIG. 3A;

FIG. 4B depicts another scenario for use of the system of FIG. 3A;

FIG. 4C depicts a further scenario for use of the system of FIG. 3A; and

FIG. 5 depicts a top view of another electrostatic lens system according to further embodiments.

### DETAILED DESCRIPTION

The embodiments described herein provide apparatus and methods for controlling an ion beam in an ion implantation system. Examples of an ion implantation system include a beamline ion implantation system. The ion implantation systems covered by the present embodiments include those that generate “spot ion beams” that have a cross-section that has the general shape of a spot, as well as ribbon ion beams that have an elongated cross-section. In the present embodiments, a novel electrostatic lens system is provided to adjust beam properties of an ion beam passing therethrough. The novel electrostatic lens system in particular may act as an electrostatic collimator and an electrostatic lens for deceleration or acceleration of the ion beam. As discussed below, in various embodiments, the electrostatic lens system may include three different electrodes that are configured to independently receive three different voltage signals. This allows the electrostatic lens to be operated in three different modes while performing collimation of an incoming ion beam: an acceleration mode in which the incoming ion beam is accelerated, a deceleration mode in which the incoming ion beam is decelerated, and a combination mode in which the incoming ion beam undergoes both acceleration and deceleration. In so doing the electrostatic lens may be effective to collimate ions over a wide range of (input ion energy)/(output ion energy) ratio for ions being treated by the electrostatic lens, especially values where the ratio is close to 1.

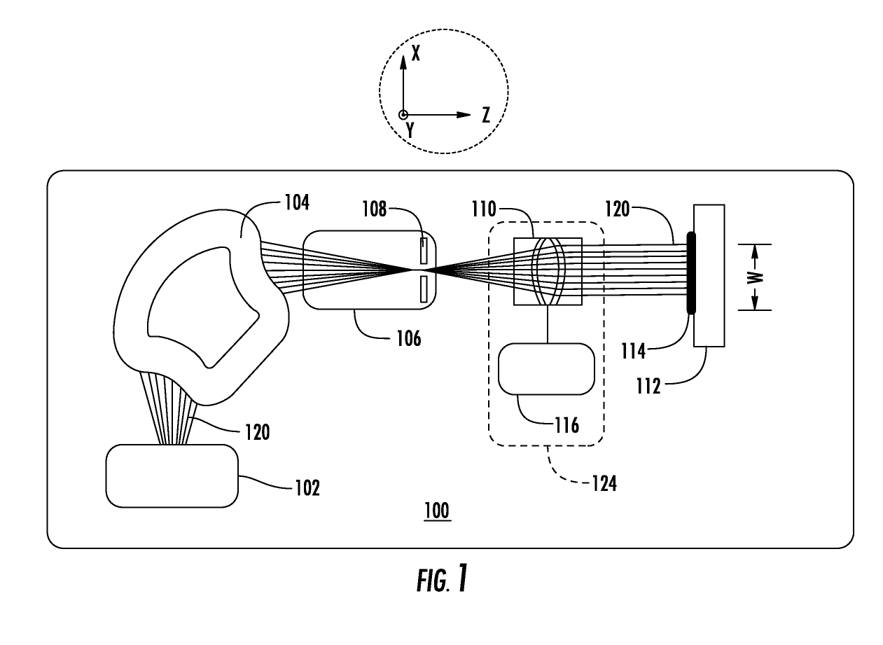

FIG. 1 presents a block diagram from a top view perspective of an ion implanter consistent with various embodiments of the disclosure. The ion implanter 100 is a beamline ion implanter that delivers an ion beam 120 to a substrate stage 112, which ion beam may be used to implant a substrate 114 positioned on the substrate stage 112. The various elements of the ion implanter 100 include an ion source 102, analyzing magnet 104, vacuum chamber 106, mass resolving slit 108, and substrate stage 112. In this embodiment, the ion implanter 100 is configured to generate an ion beam 120 as a ribbon beam and deliver the ion beam 120 to the substrate 114. The operation of various components of the ion implanter 100, including ion source 102, analyzing magnet 104, mass resolving slit 108 and substrate stage 112 are well known and further discussion of such components is omitted herein. The particular configuration illustrated in FIG. 1 may be particularly suited for medium or low energy and high current ion implantation, where ion energy may be less than 500 keV. However, the embodiments are not limited in this context

As illustrated in FIG. 1 the ion beam 120 is directed along a path in which the direction of propagation changes between ion source 102 and substrate stage 112. The ion beam 120 may be generated at the ion source 102 as a ribbon beam that is focused at the mass resolving slit 108 and subsequently fans out to impinge on the substrate. The ion beam 120 is collimated as a wide ribbon beam whose width W along the X-direction of the Cartesian coordinate system shown is comparable to a substrate width Ws in the same direction. Accordingly, when the substrate stage 112 is scanned along the Z-direction, the ion beam 120 may be provided to the entire surface of the substrate 114.

As further shown in FIG. 1, an electrostatic lens 110 is disposed downstream of the mass resolving slit 108 to collimate the ion beam 120, which is diverging as it enters the electrostatic lens 110. The electrostatic lens 110 is further configured as a deceleration/acceleration lens that may act as a triple mode electrostatic collimator. In various embodiments, the electrostatic lens 110 includes three different electrodes. The ion implanter 100 also includes a voltage supply system 116, which is electrically connected to the electrostatic lens 110 and configured to supply voltage signals independently to each of the three different electrodes. The voltage supply system 116 and electrostatic lens 110 form part of an electrostatic lens system 124 that is used to adjust operation of the electrostatic lens 110 according to different ion implantation conditions. In various embodiments, the voltage supply system 116 may include a separate voltage supply (not shown) for each electrode of the electrostatic lens 110, as well as a controller (also not shown) to coordinate voltage signals sent to the different electrodes. This allows the voltage supply system 116 to independently supply voltage to each of the three different electrodes.

Depending upon the incident energy of the ion beam 120 at the electrostatic lens 110 and the final ion beam energy to be delivered to the substrate 114, the electrostatic lens system 124 may be used to accelerate ion beam 120, decelerate ion beam 120, or transmit the ion beam 120 without energy change to the substrate, in conjunction with the collimation of the ion beam 120. This is accomplished when the voltage supply system 116 generates the appropriate voltages at each of the electrodes of the electrostatic lens 110.

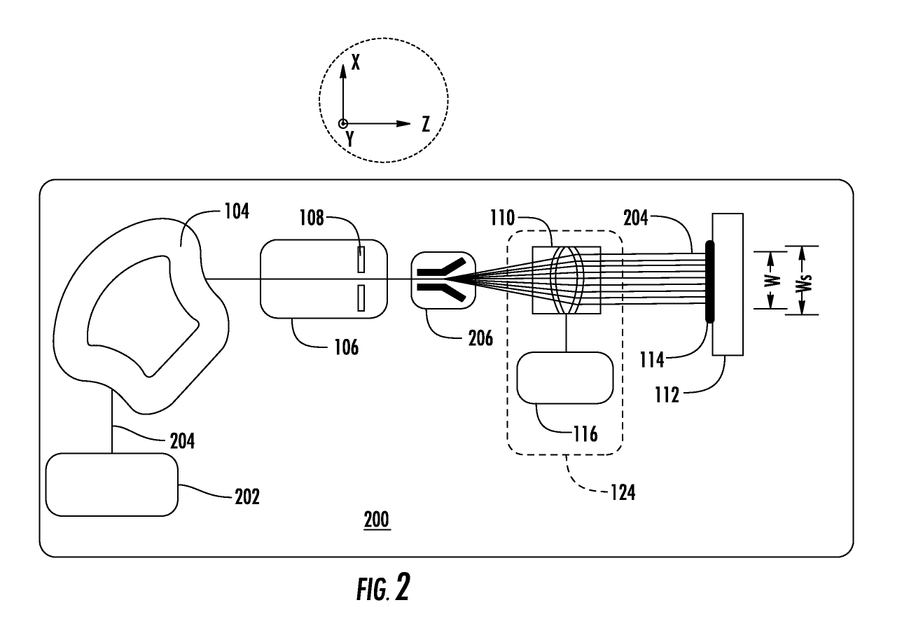

FIG. 2 presents a block diagram from a top view perspective of an ion implanter 200 consistent with further embodiments. Except as noted, the ion implanter 200 may have similar or the same components as the ion implanter 100. In particular, the ion implanter 200 is a beamline ion implanter that delivers the ion beam 204 as a scanned spot beam to the substrate stage 112, which is used to treat the substrate 114 positioned on the substrate stage 112. The ion source 202 may be configured to generate the ion beam 204 as a spot beam whose cross-sectional dimensions in the X-and Y direction are comparable, such as 20-30 mm in one example. In order to scan the ion beam 204 over a substrate 114, which may have a dimension of 300 mm along X- and Y-directions, the ion implanter 200 includes a scanner 206 positioned upstream of the electrostatic lens 110. The scanner 206 scans the ion beam 204 back and forth along the X-direction to generate a scanned beam that presents a set of diverging trajectories for ions entering the electrostatic lens 110. Similarly, to ion implanter 100, in operation the electrostatic lens system 124 may be used to accelerate ion beam 204, decelerate ion beam 204, or transmit the ion beam 204 without energy change to the substrate, in conjunction with the collimation of the ion beam 204. This is accomplished when the voltage supply system 116 generates the appropriate voltages at each of the electrodes of the electrostatic lens 110. In this case, the collimation applies to a spot beam whose average trajectory varies with time as it is scanned by the scanner 206. Accordingly, these different trajectories are collimated by the electrostatic lens 110 as illustrated.

In either of the ion implanter embodiments of FIG. 1 or FIG. 2 an electrostatic lens system 124 may be employed to properly collimate a divergent ion beam while adjusting the ion energy of an ion beam, whether the ion energy is to be increased, decreased, or remain unaltered. In particular, electrostatic lens systems of the present embodiments provide a three-electrode electrostatic lens in which the electrodes are arranged in-line in a beamline as the ion beam propagates from an upstream side of the lens to a downstream side of the lens. As used herein, “upstream” and “downstream” are used with reference to a direction of travel of the ion beam.

As detailed below the three electrodes of an electrostatic lens define two gaps: an upstream gap between the first and second electrode and a downstream gap between second and third electrode. In the present embodiments, each gap is defined by a pairing of a concave surface of one electrode with a convex surface of the other electrode. In one variant, a “double concavoconvex” lens includes a first and second electrode in which the upstream gap is defined by a concave surface on the exit (downstream) side of the first electrode and convex surface on the entrance (upstream) side of the second electrode. A downstream gap is defined by a convex surface on the exit side of the second electrode and concave surface on the entrance side of the third electrode. In another variant, a “double convexoconcave” lens includes a first and second electrode in which the first (upstream) gap is defined by a convex surface on the exit (downstream) side of the first electrode and concave surface on the entrance (upstream) side of the second electrode. A downstream gap is defined by a concave surface on the exit side of the second electrode and convex surface on the entrance side of the third electrode.

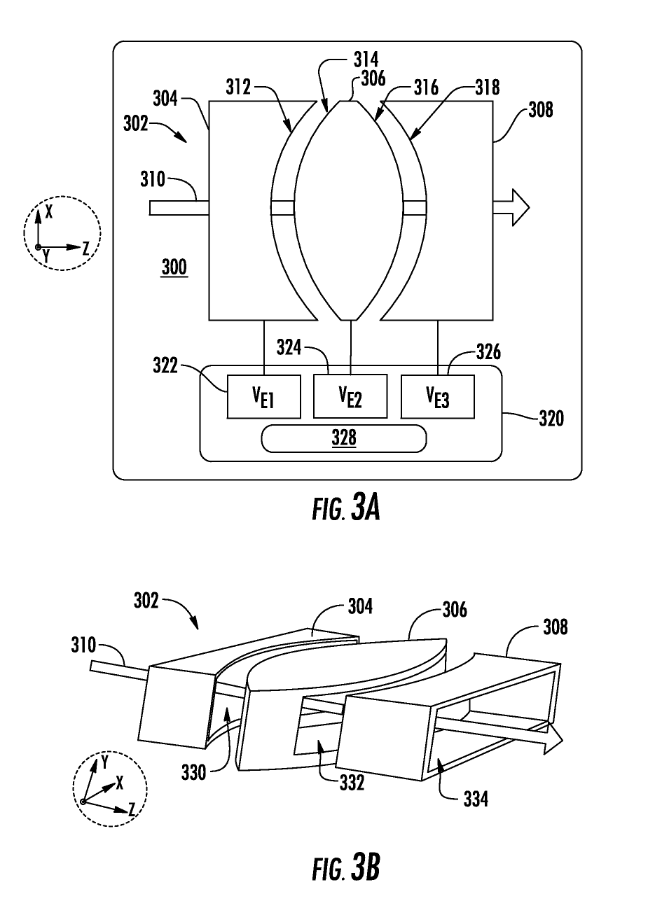

FIG. 3A illustrates a block diagram from a top view perspective of one embodiment of the electrostatic lens system 124. In this embodiment, an electrostatic lens system 300 includes three electrodes that are arranged to form a “double concavoconvex” lens, electrostatic lens 302. For purposes of illustration, in FIG. 3A it may be assumed that the electrostatic lens 302 is configured to transport an ion beam 310 from the left, upstream side, to the right, downstream side.

FIG. 3B illustrates an isometric view of the electrostatic lens 302. As illustrated, the electrostatic lens 302 includes a first electrode 304, second electrode 306, and third electrode 308, which are arranged to transport the ion beam 310 through respective openings 330, 332, and 334. As suggested by FIG. 3B, in some embodiments the openings 330, 332, 334 may each be formed by an aperture that surrounds the ion beam 310 as it propagates through the electrostatic lens 302. In other embodiments, one or more of the electrodes may be constructed from a pair of opposing parallel plates set at the same voltage and spaced apart to define the opening. For clarity, in FIG. 3B, the ion beam 310 is illustrated as a narrow ion beam, which may represent the instantaneous position of a spot beam that is being scanned as it enters the electrostatic lens 302, or may represent a central ray trajectory of a diverging ribbon beam. In either case, it is to be noted that the electrostatic lens 302 is configured to accept a diverging ion beam and collimate that ion beam before the ion beam exits the electrostatic lens 302.

As further shown in FIG. 3A, a voltage supply system 320 including multiple voltage supplies is connected to the electrostatic lens 302. In particular, a first voltage supply 322 is coupled to the first electrode 304, a second voltage supply 324 coupled to the second electrode 306, and third voltage supply 326 coupled to the third electrode 308. A controller 328 is provided to coordinate voltage signals output by the first voltage supply 322, second voltage supply 324, and third voltage supply 326. In particular, the first, second, and third voltage supplies 322, 324, 326, respectively, may operate independently of one another. For example, the controller 328 may direct each voltage supply 322, 324, and 326 to generate a voltage to be sent to respective first, second, and third electrodes 304, 306, and 308 independently of any voltage established on each other electrode. This allows the electrostatic potential (voltage) to be controlled on each electrode 304, 306, 308 in an independent fashion. As detailed below, this independent voltage control allows the electrostatic lens to operate in three different modes. In general, however, the voltage supply system 320 is configured to generate voltage signals which cause the electrostatic lens 302 to operate in a first mode in which the first electrode 304 and second electrode 306 are interoperative to accelerate and collimate the ion beam; a second mode in which the second electrode 306 and third electrode 308 are interoperative to decelerate lens and collimate the ion beam; and a third mode in which the first, second, and third electrodes 304, 306, 308, respectively, are interoperative to accelerate, decelerate, and collimate the ion beam. According to the desired beam conditions, the controller 328 may select one of the aforementioned modes.

As further shown in FIG. 3A, the first electrode 304 has a concave surface 312 on the exit side (downstream) of the first electrode 304, which faces a convex surface 314 located on the entrance side (upstream) of the second electrode 306. The terms “convex” and “concave” as used herein describe the shape of the respective surfaces with respect to the main body of the electrode in question.

The second electrode 306 further has a convex surface 316 disposed on the exit side of the second electrode 306, which faces a concave surface 318 located on the entrance side of the third electrode 308. The electrostatic lens 302 thus constitutes a double concavoconvex lens, which geometry provides flexibility for collimating diverging ion beams as described below.

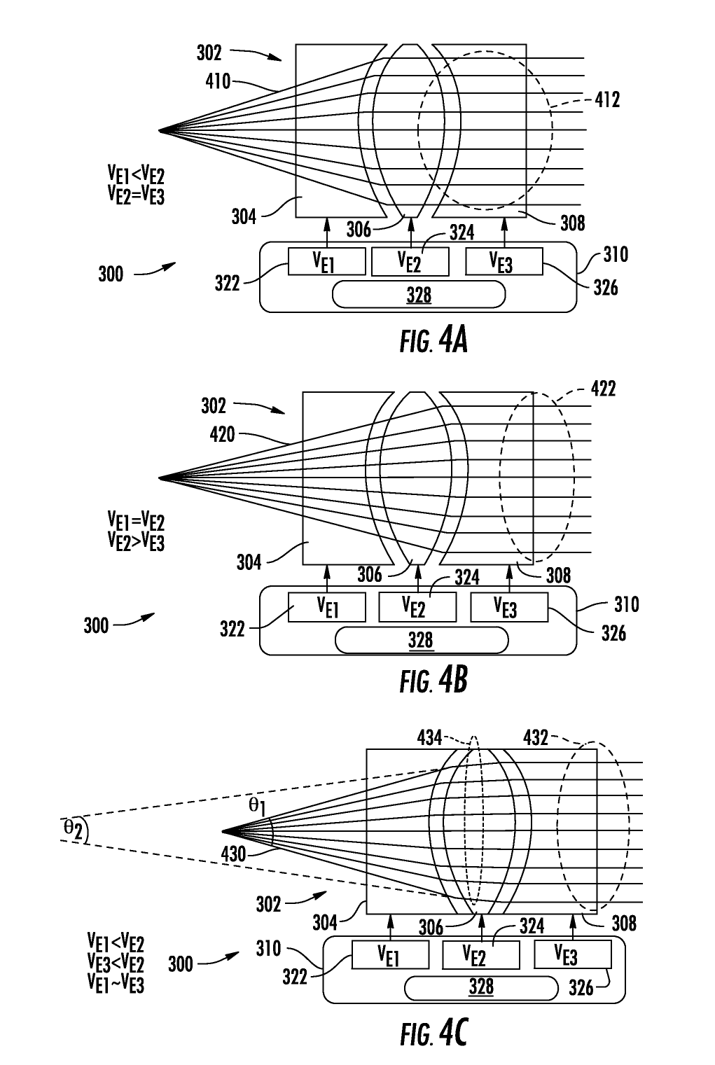

Turning now to FIGS. 4A, 4B and 4C there are shown three different scenarios for operating the electrostatic lens system 300. In particular, the FIGS. 4A, 4B, and 4C depict three different respective modes, in which the electrostatic lens system 300 operates as an acceleration lens, a deceleration lens, and a lens that both accelerates and decelerates an ion beam. In FIGS. 4A, 4B, and 4C, a respective diverging ion beam 410, 420, and 430 is generated upstream of the electrostatic lens 302. In each case the diverging ion beam 410, 420, 430 may be a scanned spot beam or a ribbon beam.

In the example of FIG. 4A, the diverging ion beam 410 enters the electrostatic lens 302 where it undergoes acceleration and collimation, exiting the electrostatic lens 302 as a collimated beam 412. To accomplish this, the first voltage supply 322 supplies a voltage V_{E1} to the first electrode 304, and the second voltage supply 324 supplies a voltage V_{E2} to the second electrode 306, where V_{E1}<V_{E2}. In one example, V_{E1} may be set to the ion beam potential of diverging ion beam 410 as it enters the electrostatic lens 302. Accordingly, when the diverging ion beam 410 traverses the upstream gap between the first electrode 304 and second electrode 306, the voltage difference V_{E2}−V_{E1} acts to accelerate ions while collimating the different ions whose initial trajectories may vary. Because of the shape of concave surface 312 of first electrode 304 and shape of convex surface 314 of second electrode 306, the effect of accelerating the diverging ion beam 410 is to collimate the ions as they traverse the electric field between first electrode 304 and second electrode 306. The resulting ions traverse the second electrode 306 as a collimated ion beam 412 having parallel trajectories. At the same time, the third voltage supply 326 supplies voltage V_{E3} to the third electrode 308, where V_{E3}=V_{E2}. Because of this the ions of the collimated ion beam 412 do not experience any electric field between the second electrode 306 and third electrode 308. Accordingly, the ions of the collimated ion beam 412 propagate as a parallel ion beam having an energy determined by the acceleration generated between the first and second electrodes.

It is to be noted that the scenario illustrated in FIG. 4A may be suitable for situations in which it is desirable to accelerate an ion beam by a substantial amount, such that the beam velocity increases by a factor of two or more after passing through the electrostatic lens. Although the shape of the electrodes 304, 306, and 308 is exemplary and not necessarily drawn to scale, a moderate curvature may be implemented in actual electrodes 304, 306, 308.

In the example of FIG. 4B, the diverging ion beam 420 enters the electrostatic lens 302 where it undergoes deceleration and collimation, exiting the electrostatic lens 302 as a collimated beam 422. To accomplish this, the first voltage supply 322 supplies a voltage V_{E1} to the first electrode 304, and the second voltage supply 324 supplies a voltage V_{E2} to the second electrode 306, where V_{E1}=V_{E2}. In one example, V_{E} and V_{E2} may be set to the potential of the diverging ion beam 420. Accordingly, when the diverging ion beam 420 traverses the gap between the first electrode 304 and second electrode 306, the diverging ion beam 420 experiences no electric field, such that the ion trajectories are not altered as they traverse either the first electrode 304 or the second electrode 306. Thus, the diverging ion beam 420 continues to propagate as a diverging beam through the second electrode 306.

At the same time, the third voltage supply 326 supplies voltage V_{E3} to the third electrode 308, where V_{E3}<V_{E2}. Because of this the ions of the diverging ion beam 420 are decelerated across an electric field established by the potential V_{E3}−V_{E2} between the second electrode 306 and third electrode 308. Because of the shape of convex surface 316 of second electrode 306 and shape of concave surface 318 of third electrode 308, the effect of decelerating the diverging ion beam 420 is to collimate the ions as they traverse the electric field between second electrode 306 and third electrode 308. Accordingly, the diverging ion beam 420 is collimated to create the collimated ion beam 422 which exits the electrostatic lens 302.

It is to be further noted that the scenario illustrated in FIG. 4B may be suitable for situations in which it is desirable to decelerate an ion beam by a substantial amount, such that the beam velocity decreases by a factor of two or more after passing through the electrostatic lens.

In the example of FIG. 4C, the diverging ion beam 430 enters the electrostatic lens 302 where it undergoes collimation, exiting the electrostatic lens 302 as a collimated beam 432. In the scenario of FIG. 4C, the electrostatic lens 302 is configured to operate in a combination acceleration/deceleration mode, or simply “combination mode.” In the combination mode, voltages are established on the respective electrodes of the electrostatic lens 302 to apply an initial acceleration to the incoming diverging ion beam 430, followed by a deceleration to the now-accelerated ion beam.

To accomplish this, the first voltage supply 322 supplies a voltage V_{E1} to the first electrode 304, and the second voltage supply 324 supplies a voltage V_{E2} to the second electrode 306, where V_{E1}<V_{E2}. Accordingly, when the diverging ion beam 430 traverses the gap between the first electrode 304 and second electrode 306, the diverging ion beam 430 experiences an accelerating electric field, such that the ion trajectories are altered as they traverse the second electrode 306. As further shown in FIG. 4C the difference in voltages V_{E2}−V_{E1} is set so that the ion trajectories are not completely collimated, wherein an accelerated diverging ion beam 434 propagates through the second electrode 306. In this case the accelerated diverging ion beam 434 is partially collimated in that the divergence angle θ2 of the accelerated diverging ion beam 434 is less than the divergence angle θ1 of the diverging ion beam 430 as it enters the electrostatic lens 302.

At the same time, the third voltage supply 326 supplies voltage V_{E3} to the third electrode 308 where V_{E3}<V_{E2}. Because of the shape of convex surface 316 of second electrode 306 and shape of concave surface 318 of third electrode 308, the effect of decelerating the accelerated diverging ion beam 434 is to collimate the ions as they traverse the electric field between second electrode 306 and third electrode 308. Accordingly, the diverging ion beam 430 is collimated in two steps as it traverses the electrostatic lens 302.

For the scenario of FIG. 4C in various embodiments, the voltages V_{E3} and V_{E1} may be equal or may vary between one another within a threshold. The scenario of FIG. 4C thus depicts a mode of operation that is appropriate when the change in ion beam energy produced by an electrostatic collimator is to be maintained below a threshold. In some examples, the combination mode of FIG. 4C may be applied when a given ratio falls below a certain threshold. For example, a ratio of incident ion velocity Vo of ions entering an electrostatic collimator to final ion velocity Vi of ions after exiting the electrostatic collimator may be defined as V₀/V₁=k. In some instances, the electrostatic lens 302 may be set to operate in combined mode when the value of k is between 0.5 and 2, and more particularly when the value of k is equal to 1. Thus, in one implementation using a divergent ion beam whose initial ion energy is 20 keV, the combined mode may be used when the final ion energy is to range between 5 keV and 80 keV, since ion energy is proportional to square of velocity.

In this manner, the triple mode operation of the electrostatic lens 302 facilitates operation as an electrostatic collimator and acceleration/deceleration lens over a wide range of (input ion energy)/(output ion energy) values. In particular, when final ion velocity after collimation does not deviate by more than a factor of two over initial ion velocity before collimation, the present embodiments provide distinct advantage over known collimator systems. Notably, in the present embodiments, operation of a combined mode is not restricted to this particular range of ion velocity ratios, but may be employed over a wider or narrower range in other embodiments. Accordingly, the present embodiments increase the useful operating range of ion energies especially in the low energy range in scenarios in which modest acceleration or deceleration is to be performed during collimation of an ion beam.

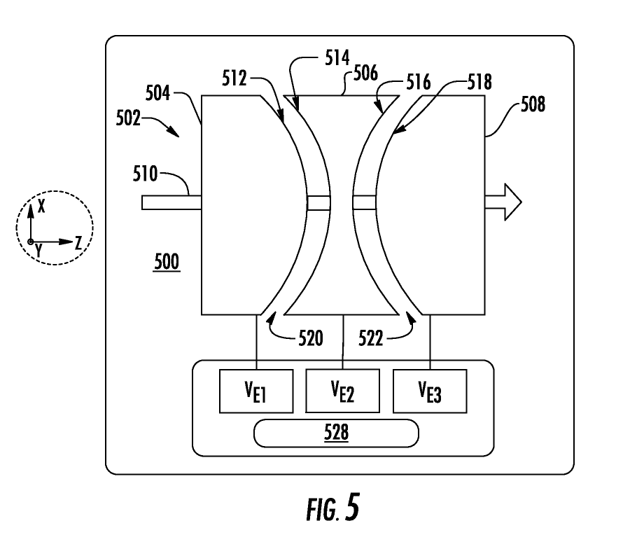

FIG. 5 depicts a top view of another electrostatic lens system 500 according to further embodiments. Instead of a “double concavoconvex” lens, is the electrostatic lens system includes an electrostatic lens 502 that is constructed as a “double convexoconcave” lens. A first electrode 504 has a first convex surface 512 on an exit side with respect to the ion beam 510, which faces a first concave surface 514 disposed on a second electrode 506. The second electrode 506 also includes a second concave surface 516 disposed on the exit side and facing a second convex surface 518 on a third electrode 508. In operation, a first gap 520 between first convex surface 512 to first concave surface 514 may be used as a deceleration field, providing some collimation, and the second gap 522 from second convex surface 516 to second concave surface 518 may be used as an acceleration field, again providing collimation. In particular, the controller 528 may operate the electrostatic lens system 500 in an acceleration mode, deceleration mode or combined mode. As with the electrostatic lens system 300 of FIGS. 3A, 3B, the two ratios can be set in the combined mode to allow good optics even for a total ratio of incident ion energy to output ion energy close to unity. In the acceleration mode, the first electrode 504 and second electrode 506 are set at a first potential and the third electrode 508 is set at a second potential higher than the first potential; in the deceleration mode, the first electrode 504 is set at a first potential and the second electrode 506 and third electrode 508 are set at a second potential lower than the first potential; and in the combined mode the first electrode 504 is set at a first potential, the second electrode 506 is set at a second potential lower than the first potential, and the electrode 508 is set at a third potential higher than the second potential. As with the embodiment illustrated in FIG. 4C, when operated in combined mode the electrostatic lens 502 is operative to collimate an ion beam 510 in two steps across the first gap 520 and second gap 522 such that the electrostatic lens 502 adds convergence at both gaps 520, 522, although in this case an ion beam 510 is first decelerated and then accelerated

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of treating a diverging ion beam, comprising;
accelerating and partially collimating the diverging ion beam between a first electrode and a second electrode to create an accelerated and partially collimated ion beam; and
decelerating the accelerated and partially collimated ion beam between the second electrode and a third electrode to generate a fully collimated ion beam.

2. The method of claim 1, wherein a ratio of ion velocity of the diverging ion beam to ion velocity of the collimated ion beam is between 0.5 and 2.0.

3. The method of claim 1, further comprising:
providing the first electrode with a first concave surface on an exit side of the first electrode;
providing the second electrode with a first convex surface opposite the exit side of the first electrode and a second convex surface on an exit side of the second electrode; and
providing the third electrode with a second concave surface facing the exit side of the second electrode.

4. The method of claim 1, wherein the diverging ion beam comprises a first diverging ion beam, the method further comprising:
accelerating a second diverging ion beam between the first and second electrodes to form a second collimated ion beam, wherein a ratio of ion velocity of the second diverging ion beam to ion velocity of the second collimated ion beam is less than 0.5.

5. The method of claim 1, wherein the diverging ion beam comprises a first diverging ion beam, the method further comprising:
decelerating a third diverging ion beam between the second and third electrodes to form a third collimated ion beam, wherein a ratio of ion velocity of the third diverging ion beam to ion velocity of the third collimated ion beam is greater than 2.

6. The method of claim 1, further comprising providing a first voltage from a first voltage supply to the first electrode, providing a second voltage from a second voltage supply to the second electrode, and providing a third voltage from a third voltage supply to the third electrode.

7. The method of claim 6, further comprising adjusting at least one of the first voltage, the second voltage, and the third voltage independently of at least one other of the first voltage, the second voltage, and the third voltage.

8. The method of claim 6, further comprising a controller coordinating operation of the first voltage supply, the second voltage supply, and the third voltage supply to achieve a desired mode of operation.

9. The method of claim 1 further comprising:
providing the first electrode with a first convex surface on an exit side of the first electrode;
providing the second electrode with a first concave surface opposite the exit side of the first electrode and a second concave surface on an exit side of the second electrode; and
providing the third electrode with a second convex surface facing the exit side of the second electrode.

10. A method of treating a diverging ion beam, comprising;
providing a first electrode with a first concave surface on an exit side of the first electrode;
providing a second electrode with a first convex surface opposite the exit side of the first electrode and a second convex surface on an exit side of the second electrode;
providing a third electrode with a second concave surface facing the exit side of the second electrode; and
projecting the diverging ion beam toward the first, second, and third electrodes.

11. The method of claim 10, further comprising providing a first voltage from a first voltage supply to the first electrode, providing a second voltage from a second voltage supply to the second electrode, and providing a third voltage from a third voltage supply to the third electrode.

12. The method of claim 11, further comprising adjusting at least one of the first voltage, the second voltage, and the third voltage independently of at least one other of the first voltage, the second voltage, and the third voltage.

13. The method of claim 11, further comprising a controller coordinating operation of the first voltage supply, the second voltage supply, and the third voltage supply to achieve a desired mode of operation.

14. The method of claim 11, further comprising accelerating and collimating the diverging ion beam by making the second voltage greater than the first voltage and making the third voltage equal to the second voltage.

15. The method of claim 11, further comprising decelerating and collimating the diverging ion beam by making the second voltage equal to the first voltage and making the third voltage greater than the second voltage.

16. The method of claim 11, further comprising collimating the diverging ion beam by making the second voltage greater than the first voltage and making the third voltage less than the second voltage.

17. A method of treating a diverging ion beam, comprising;
providing a first electrode with a first convex surface on an exit side of the first electrode;
providing a second electrode with a first concave surface opposite the exit side of the first electrode and a second concave surface on an exit side of the second electrode;
providing a third electrode with a second convex surface facing the exit side of the second electrode; and
projecting the diverging ion beam toward the first, second, and third electrodes.

18. The method of claim 17, further comprising providing a first voltage from a first voltage supply to the first electrode, providing a second voltage from a second voltage supply to the second electrode, and providing a third voltage from a third voltage supply to the third electrode.

19. The method of claim 18, further comprising adjusting at least one of the first voltage, the second voltage, and the third voltage independently of at least one other of the first voltage, the second voltage, and the third voltage.

20. The method of claim 18, further comprising a controller coordinating operation of the first voltage supply, the second voltage supply, and the third voltage supply to achieve a desired mode of operation.

21. The method of claim 18, further comprising accelerating and collimating the diverging ion beam by making the second voltage equal to the first voltage and making the third voltage greater than the second voltage.

22. The method of claim 18, further comprising decelerating and collimating the diverging ion beam by making the first voltage greater than the second voltage and making the third voltage equal to the second voltage.

23. The method of claim 18, further comprising collimating the diverging ion beam by making the first voltage greater than the second voltage and making the third voltage greater than the second voltage.
